(19) United States
(12) Patent Application Publication
(10) Pub. No.: US 2009/0170336 A1
(43) Pub. Date: Jul. 2, 2009

(54) METHOD FOR FORMING PATTERN OF SEMICONDUCTOR DEVICE

(75) Inventors: Keun Do Ban, Yongin-si (KR); Cheol Kyu Bok, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/163,817

(22) Filed: Jun. 27, 2008

(30) Foreign Application Priority Data
Dec. 28, 2007 (KR) 10-2007-0140860

(51) Int. Cl. H01L 21/308

(52) U.S. Cl. 438/751; 257/E21.038; 257/E21.039; 257/E21.219; 257/E21.236; 257/E21.235

(57) ABSTRACT

A method for forming a pattern of a semiconductor device comprises forming a spacer with an oxide film in a SPT process, and removing the spacer formed to have a horn shape before etching an underlying layer, so that the horn shape is transcribed in a lower portion, thereby facilitating control of critical dimension in etching the underlying layer so as to improve a characteristic of the device.

A method for forming a pattern of a semiconductor device of the present invention comprises: forming an underlying layer and a hard mask layer over a semiconductor substrate; forming a sacrificial pattern over the hard mask layer; forming a spacer at both sides of the sacrificial pattern; removing the sacrificial pattern to remain the spacer; etching the hard mask layer with the spacer as a mask to form a hard mask pattern; removing the spacer; and etching the underlying layer with the hard mask pattern as a mask.

### CROSS-REFERENCES TO RELATED APPLICATIONS

Priority to Korean patent application number 10-2007-0140860, filed on Dec. 28, 2007, which is incorporated by reference in its entirety, is claimed.

### BACKGROUND OF THE INVENTION

The present invention relates to a method for forming a pattern of a semiconductor device using a Spacer Patterning Technology (SPT).

As a pattern size is reduced due to the high-integration of semiconductor devices, various approaches have been made in equipment and processes to obtain a fine pattern. For example, an exposure wavelength is reduced, and a size of lens is increased in order to obtain a fine pattern.

The above-described methods requires development of equipment which increases cost, so that there is a difficulty in the management of equipment.

Another method for forming a fine pattern of high-integration using conventional equipment includes a double exposure technology using two exposure masks and a Spacer Patterning Technology (SPT) using three exposure masks.

FIGS. 1a to 1d are cross-sectional diagrams illustrating a conventional method for forming a pattern of a semiconductor device.

Referring to FIG. 1a, an underlying layer 110, a sacrificial film 120 and a hard mask layer 130 are formed over a semiconductor substrate 100.

An anti-reflection film 140 and a photoresist pattern 150 having a line shape are formed over the hard mask layer 130 of a cell region I. The underlying layer 110 includes an amorphous carbon layer 103 and a nitride film 105.

Referring to FIG. 1b, the anti-reflection film 140 and the hard mask layer 130 are etched with the photoresist pattern 150 as a mask to remove the anti-reflection film 140 and the first photoresist pattern 150.

The sacrificial film 120 is etched with the hard mask pattern as a mask to obtain a sacrificial pattern 120a. The hard mask pattern is removed.

A spacer 155 is formed at sidewalls of the sacrificial pattern 120a.

The spacer 155 includes a polysilicon layer and a nitride film.

Referring to FIG. 1c, the sacrificial pattern 120a is removed so that the spacer 155 remains. The sacrificial pattern 120a is removed by a wet etching process.

A second photoresist pattern 160 for forming a pad is formed over the underlying layer 110 of a peripheral circuit region (II).

The underlying layer 110 is etched with the spacer 155 and the second photoresist pattern 160 as a mask to form an underlying pattern 110a.

Referring to FIG. 1d, The spacer 155 and the second photoresist pattern 160 are removed.

A third photoresist pattern (not shown) is formed which is used to expose the line end of the underlying pattern 110a.

The third photoresist pattern is a cutting mask for separating the underlying pattern part formed by the spacer of the line end region generated from deposition of a spacer material layer.

A part of the underlying pattern 110a disposed at the line end is removed with the third photoresist pattern as a mask to separate each line, thereby removing the third photoresist pattern.

FIGS. 2a to 2c are photographs illustrating patterns formed by a conventional method.

FIG. 2a shows a photograph after a spacer 155 remains. There are spaces A1 and B1 between spacers 155.

FIG. 2b shows a photograph after a nitride film 105 is etched with the spacer 155 as a mask. There are spaces A2 and B2 between hard mask patterns. FIG. 2c shows a photograph after an amorphous carbon layer 103 is etched with the nitride pattern as a mask. There are spaces A3 and B3 between amorphous carbon patterns.

Referring to FIGS. 2a to 2c, while an etching process is performed with a horn-shaped spacer as a mask, critical dimensions (A1, A2, A3) of the spaces and critical dimensions (B1, B2, B3) of the region where a sacrificial pattern is formed are not uniform.

In the above-described conventional method for forming a pattern of a semiconductor device, the hard mask layer and the underlying layer are etched with the horn-shaped spacer as a mask. As a result, the uniformity of the critical dimension (CD) of the final pattern is degraded, so that it is difficult to control the CD.

### BRIEF SUMMARY OF THE INVENTION

Various embodiments of the present invention relate to a method for forming a pattern of a semiconductor device that comprises forming a spacer including an oxide film in a SPT process and removing the spacer formed to have a horn shape before etching an underlying layer, so that the horn shape is not transcribed in a lower portion, thereby facilitating CD control in etching the underlying layer so as to improve a characteristic of the device.

According to an embodiment of the present invention, a method for forming a pattern of a semiconductor device comprises: forming an underlying layer and a hard mask layer over a semiconductor substrate; forming a sacrificial pattern over the hard mask layer; forming a spacer at both sides of the sacrificial pattern; removing the sacrificial pattern to remain the spacer; etching the hard mask layer with the spacer as a mask to form a hard mask pattern; removing the spacer; and etching the underlying layer with the hard mask pattern as a mask.

The underlying layer includes one selected from the group consisting of an amorphous carbon layer, a nitride film and combinations thereof. The hard mask layer includes a polysilicon layer. The sacrificial pattern includes one selected from the group consisting of an amorphous carbon layer, a spin on carbon (SOC) layer and combinations thereof. The sacrificial pattern is formed to have a line/space shape, and the ratio of line:space is 1:3. The removing-the-sacrificial-pattern step is performed with O₂ plasma.

The forming-a-spacer step includes: depositing an oxide film over the resulting structure including the sacrificial pattern; and performing an etch-back process to form a spacer at both sides of the sacrificial pattern. The oxide film is deposited at a temperature ranging from 100 to 200° C. The removing-the-spacer step is performed by a wet dip-out process using a buffer oxide etchant (BOE) solution.

### BRIEF DESCRIPTION OF THE DRAWINGS

FIGS. 1a to 1d are cross-sectional diagrams illustrating a conventional method for forming a pattern of a semiconductor device.

FIGS. 2a to 2c are photographs illustrating patterns formed by a conventional method.

FIGS. 3a to 3g are cross-sectional diagrams illustrating a method for forming a pattern of a semiconductor device according to an embodiment of the present invention.

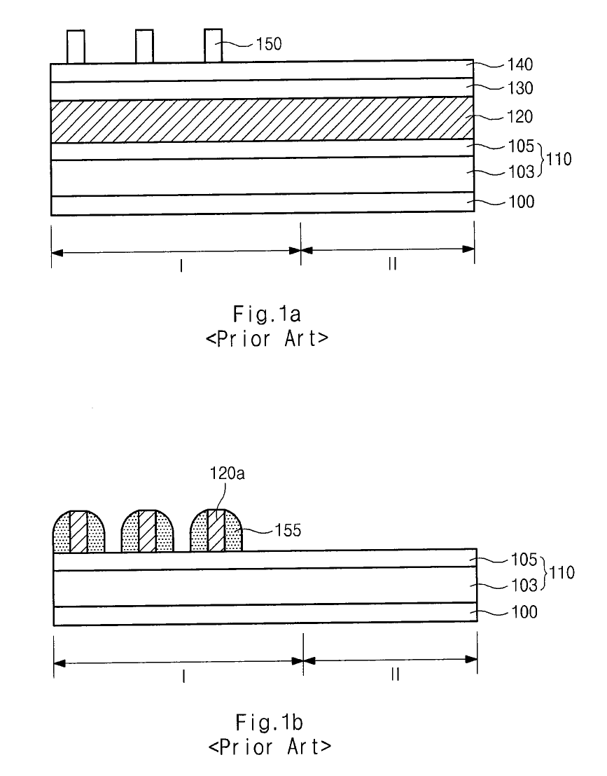

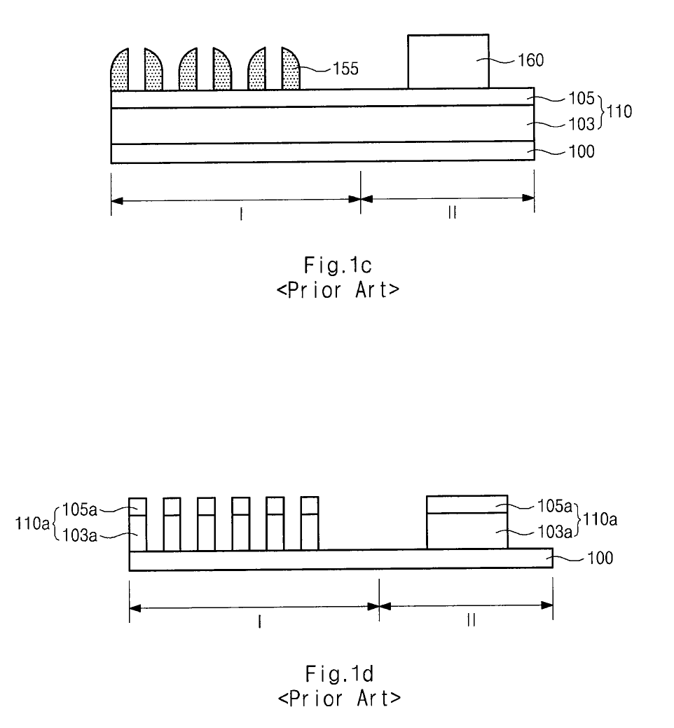

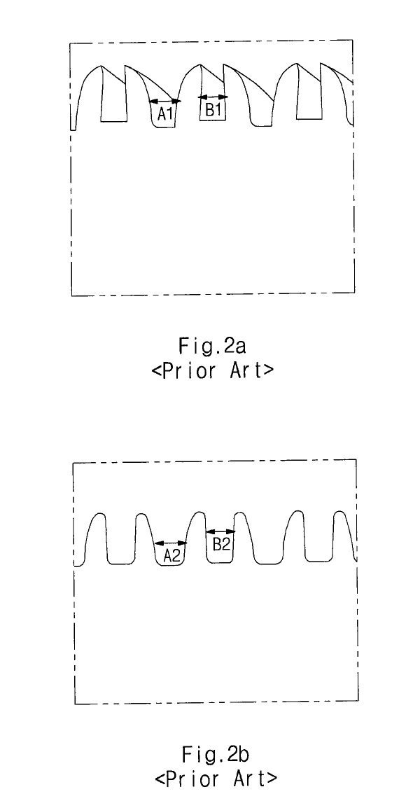

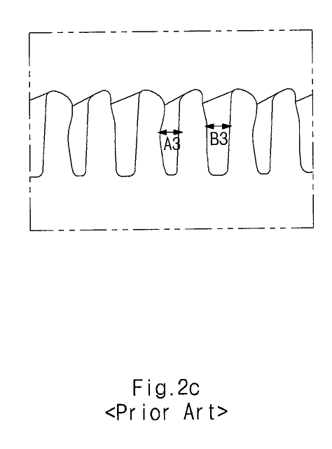

### DESCRIPTION OF EMBODIMENTS

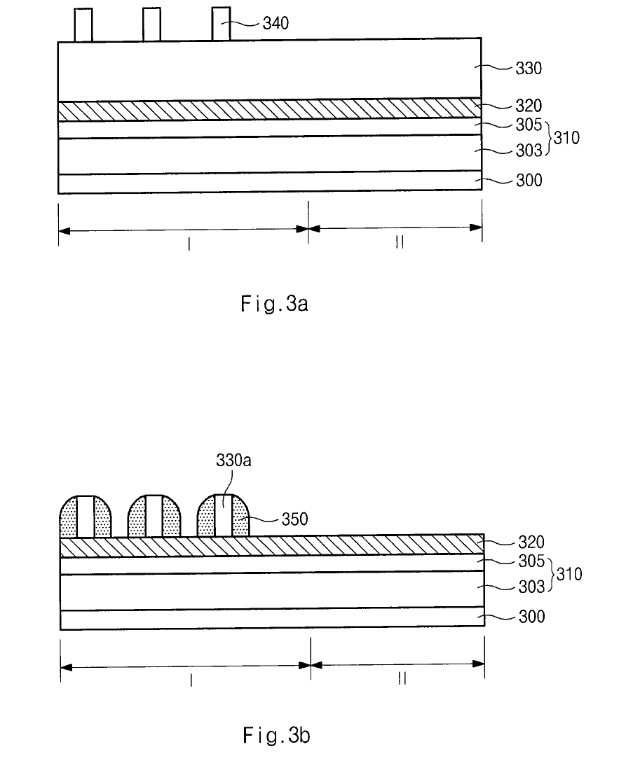

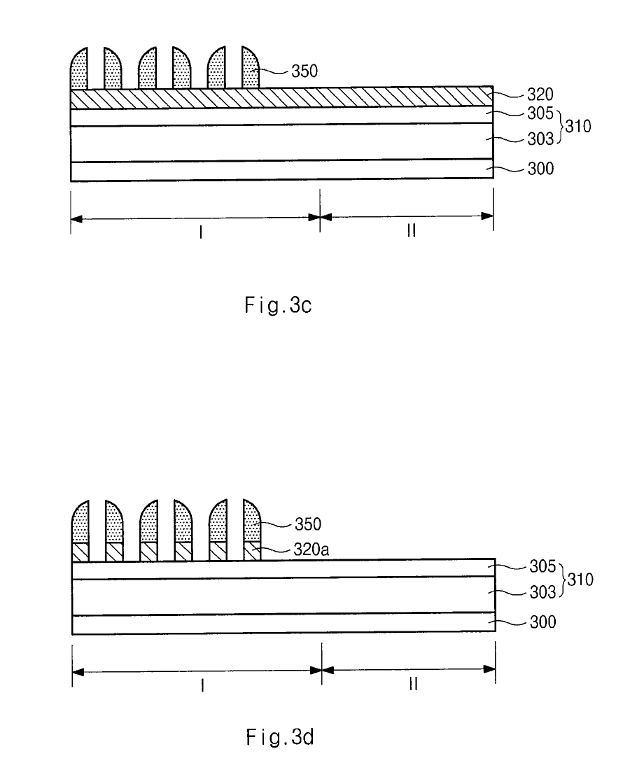

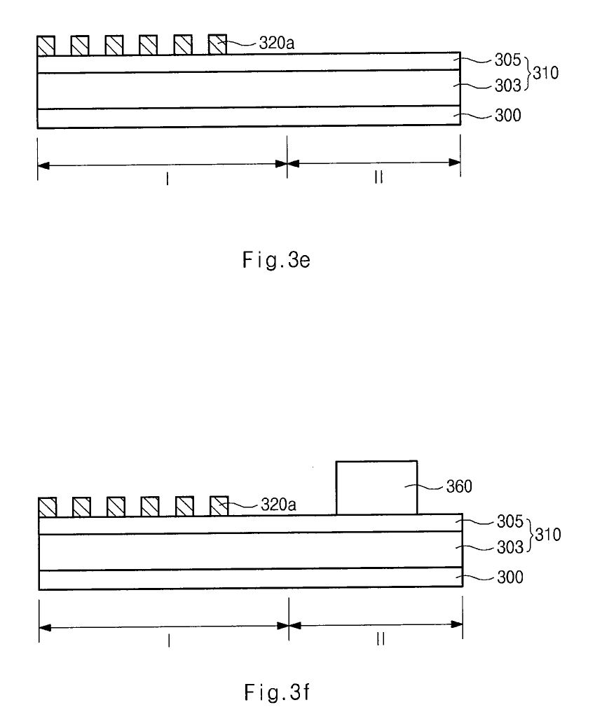

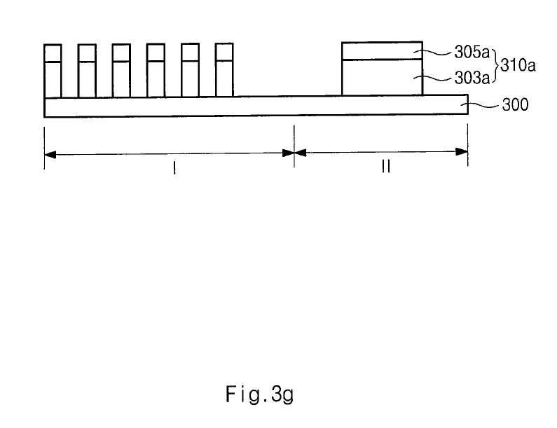

FIGS. 3a to 3g are cross-sectional diagrams illustrating a method for forming a pattern of a semiconductor device according to an embodiment of the present invention.

Referring to FIG. 3a, an underlying layer 310, a hard mask layer 320 and a sacrificial film 330 are sequentially formed over a semiconductor substrate 300 of a cell region (I) and a peripheral circuit region (II).

The underlying layer 310 includes an amorphous carbon layer 303 and a nitride film 305. The hard mask layer 320 includes a polysilicon layer.

The sacrificial film 330 may include an amorphous carbon layer, a spin on carbon (SOC) layer and combinations thereof.

A first photoresist pattern 340 is formed over the sacrificial film 330 of the cell region (I). The first photoresist pattern 340 includes a line and a space and the ratio of line to space is 1:3. The first photoresist pattern 340 has a thickness ranging from 800 to 1200 Å.

Since the thickness of the first photoresist pattern 340 is thin, a silicon oxide nitride (SiON) film, a multi function hard mask and combinations thereof can be formed under the first photoresist pattern 340.

Referring to FIG. 3b, the sacrificial film 330 is etched with the first photoresist pattern 340 as a mask to form a sacrificial pattern 330a. An oxide film (not shown) having a given thickness is deposited over the resulting structure including the sacrificial pattern 330a. The sacrificial film (not shown) may include an oxide film material that can be deposited at a temperature ranging from 100 to 200° C. An etch-back process is performed to form a spacer 350 at both sides of the sacrificial pattern 330a.

Referring to FIG. 3c, the sacrificial pattern 330a is removed leaving the spacer 350. The sacrificial pattern 330a is removed by O₂ plasma.

A second photoresist pattern (not shown) is formed which Is covers the regions of the semiconductor substrate where the spacer 350 is not formed. The second photoresist pattern (not shown) is a cutting mask for separating the spacer part of the line end region generated from deposition of a spacer material layer.

A part of the spacer 350 disposed at the line end is removed with the second photoresist pattern (not shown) as a mask to separate each line, thereby removing the second photoresist pattern.

Referring to FIGS. 3d and 3e, the hard mask layer 320 is etched with the spacer 350 as a mask to form a hard mask pattern 320a.

The spacer 350 is removed. The spacer 350 includes an oxide film material, which can be removed by a wet dip-out process.

The dip-out process may be performed using a buffer oxide etchant (BOE) solution. The polysilicon layer and a low-pressure (LP) nitride film formed under the spacer 350 are not etched by the BOE solution.

Referring to FIG. 3f, a third photoresist pattern 360 for forming a pad is formed over the peripheral circuit region (II).

Referring to FIG. 3g, In the cell region (I) and the peripheral circuit region (II), the underlying layer 310 is etched with the hard mask pattern 320a and the third photoresist pattern 360 as a mask to form a pattern 310a.

After the spacer remains, the lower hard mask layer is etched with the spacer as a mask to form the hard mask pattern. After the spacer is removed, the underlying layer is etched with the hard mask pattern as a mask, thereby preventing CD non-uniformity of patterns generated when the lower layer is etched with the horn-shaped spacer.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for forming a pattern of a semiconductor device, the method comprising:
forming an underlying layer and a hard mask layer over a semiconductor substrate;
forming a sacrificial pattern over the hard mask layer;
forming first and second spacers at first and second sides, respectively, of the sacrificial pattern;
removing the sacrificial pattern, the first and second spacers remaining over the hard mask layer;
etching the hard mask layer using the first and second spacers as a mask to form a hard mask pattern;
removing the first and second spacers; and
etching the underlying layer using the hard mask pattern as a mask.

2. The method according to claim 1, wherein the underlying layer includes one selected from the group consisting of an amorphous carbon layer, a nitride film and a combination thereof.

3. The method according to claim 1, wherein the hard mask layer includes a polysilicon layer.

4. The method according to claim 1, wherein the sacrificial pattern includes one selected from the group consisting of an amorphous carbon layer, a spin on carbon (SOC) layer and a combination thereof.

5. The method according to claim 1, wherein the sacrificial pattern is formed to have a line/space shape, and the ratio of line space is 1:3.

6. The method according to claim 1, wherein the removing-the-sacrificial-pattern step is performed with O₂ plasma.

7. The method according to claim 1, wherein the forming-first-and-second-spacers step includes:
depositing an oxide film over the sacrificial pattern; and
performing an etch-back process to form the first and second spacers at the first and second sides of the sacrificial pattern.

8. The method according to claim 7, wherein the oxide film is deposited at a temperature ranging from 100 to 200° C.

9. The method according to claim 1, wherein the removing-the-first-and-second-spacers step is performed by using a wet dip-out process using a buffer oxide etchant (BOE) solution.

10. The method according to claim 1, wherein the sacrificial pattern-forming step includes:
forming a first photoresist pattern over the sacrificial film; and
etching the sacrificial film with the first photoresist pattern as a mask to obtain a sacrificial pattern.

11. The method according to claim 10, wherein one selected from the group consisting of a silicon oxide nitride (SiON) film, a multi function hard mask and a combination thereof is formed under the first photoresist pattern.

12. The method according to claim 1, further comprising:
forming a second photoresist pattern that exposes the outer side of the semiconductor substrate where the first and second spacers are formed; and
removing a part of the first spacer disposed at the line end with the second photoresist pattern as a mask to separate each line, thereby removing the second photoresist pattern.

13. The method according to claim 1, further comprising:
forming a third photoresist pattern for forming a pad over the peripheral circuit region; and
etching the underlying layer on the peripheral circuit region with the third photoresist pattern as a mask to form a pattern.
